(19) United States
(12) Patent Application Publication
(10) Pub. No.: US 2025/0071930 A1
(43) Pub. Date: Feb. 27, 2025

(54) MODULAR STACKED EQUIPMENT ENCLOSURE FOR DATA CENTER

(71) Applicant: Integra Mission Critical, LLC, Dallas, TX (US)

(72) Inventors: John Kolar, Clearwater, FL (US); Christopher Fulton, Tobermory (CA); William Phar, Harrow (CA); Gregory MacNeill, Plano, TX (US)

(21) Appl. No.: 18/812,907

(22) Filed: Aug. 22, 2024

Related U.S. Application Data
(60) Provisional application No. 63/578,118, filed on Aug. 22, 2023.

(51) Int. Cl. H05K 7/14; H05K 7/20

(52) U.S. Cl. CPC H05K 7/1497; H05K 7/2079; H05K 7/20272

(57) ABSTRACT

A system includes a stacked enclosure comprising multiple structural modules arranged in a vertically oriented stack. Each structural module is disposed at a different vertical level, and each structural module has a substantially same footprint. Each structural module is configured to house support equipment for a data center. The system also includes one or more interstitial layers disposed between adjacent structural modules.

### CROSS-REFERENCE TO RELATED APPLICATIONS AND PRIORITY CLAIM

This application claims priority under 35 U.S.C. § 119(e) to U.S. Provisional Patent Application No. 63/578,118 filed on Aug. 22, 2023, which is hereby incorporated by reference in its entirety.

### TECHNICAL FIELD

Embodiments of the present disclosure relate to data centers and, in particular, to modular, stacked equipment enclosures for use with data centers.

### BACKGROUND

As the need for data centers increases, there is also a need for increasing density in the technical supporting infrastructure (for example, electrical and cooling support equipment) for the data center. That is, an increase in power capacity and cooling capacity for a given space or location can enhance the capabilities of the data center. In addition, the ability to quickly build and deploy such supporting infrastructure is also important, since a reduction in the time to market can have a direct impact on financial success of the data center.

### SUMMARY

This disclosure provides various modular, stacked equipment enclosures for use with data centers.

In a first embodiment, a system includes a stacked enclosure comprising multiple structural modules arranged in a vertically oriented stack. Each structural module is disposed at a different vertical level, and each structural module has a substantially same footprint. Each structural module is configured to house support equipment for a data center. The system also includes one or more interstitial layers disposed between adjacent structural modules.

In a second embodiment, a system includes multiple stacked enclosures arranged adjacent each other in a row. Each stacked enclosure includes multiple structural modules arranged in a vertically oriented stack. Each structural module is disposed at a different vertical level, and each structural module has a substantially same footprint. Each structural module is configured to house support equipment for a data center. Each stacked enclosure also includes one or more interstitial layers disposed between adjacent structural modules.

Other technical features may be readily apparent to one skilled in the art from the following figures, descriptions, and claims.

### BRIEF DESCRIPTION OF THE DRAWINGS

FIGS. 1 and 2 illustrate an example stacked enclosure for data center support equipment according to this disclosure;

FIG. 3 illustrates further details of a fuel storage module forming part of the stacked enclosure of FIG. 1 according to this disclosure;

FIG. 4 illustrates further details of a PDC module forming part of the stacked enclosure of FIG. 1 according to this disclosure;

FIG. 5 illustrates further details of a generator module forming part of the stacked enclosure of FIG. 1 according to this disclosure;

FIGS. 6A and 6B illustrate further details of a chiller module forming part of the stacked enclosure of FIG. 1 according to this disclosure;

FIGS. 7 through 9 illustrate example trusses that can be used in the construction of one or more modules of the stacked enclosure of FIG. 1 according to this disclosure; and

FIG. 10 illustrates an elevation view of an example data center installation that includes multiple stacked enclosures according to this disclosure.

### DETAILED DESCRIPTION

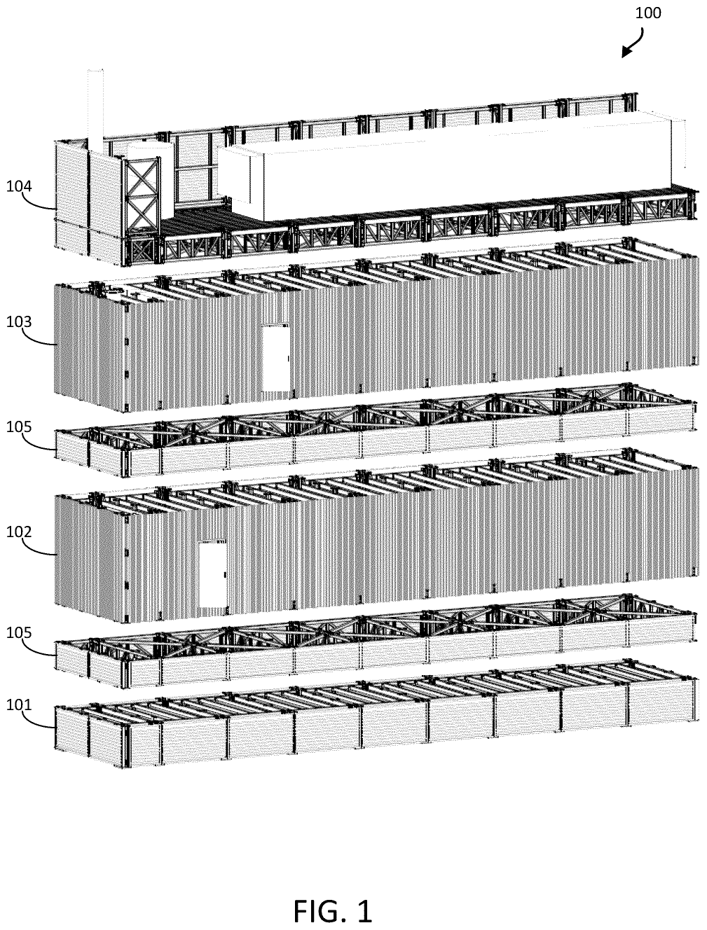

FIGS. 1 through 10, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

For simplicity and clarity, some features and components are not explicitly shown in every figure, including those illustrated in connection with other figures. It will be understood that all features illustrated in the figures may be employed in any of the embodiments described. Omission of a feature or component from a particular figure is for purposes of simplicity and clarity and is not meant to imply that the feature or component cannot be employed in the embodiments described in connection with that figure. It will be understood that embodiments of this disclosure may include any one, more than one, or all of the features described here. Also, embodiments of this disclosure may additionally or alternatively include other features not listed here.

As discussed above, as the need for data centers increases, there is also a need for increased density in the technical supporting infrastructure (for example, electrical and cooling support equipment) for the data center. That is, an increase in power capacity and cooling capacity for a given space or location can enhance the capabilities of the data center. In addition, the ability to quickly build and deploy such supporting infrastructure is also important, since a reduction in the time to market can have a direct impact on financial success of the data center.

In typical conventional data center implementations, the various components of the supporting infrastructure (e.g., generators, cooling equipment, switch gear, uninterruptible power supplies (UPSs), batteries, fuel storage, and the like) are typically planned and installed on a site-by-site basis dependent on geography, ground conditions, site risks, and available building options. This typically requires extensive per site engineering, approvals, and lengthy on-site build, integration and coordination activities.

Existing systems typically include a ground mounted generator, a ground mounted electrical building, and a chiller system that may also be assembled at or near ground level. This results in a horizontally oriented, non-modular data center system that occupies substantial ground space and is not easily scaled.

Various attempts at reducing site build complexity have been made, including the limited use of modular building and modular subsystem development. Such techniques have generally been limited to ISO shipping container building blocks, limited in vertical deployment capability or size of block, limited in integration, or a combination of these.

To address these and other issues, embodiments of the present disclosure provide modular, stacked equipment enclosures for use with data centers. The disclosed equipment enclosures are multi-level enclosures for data center support equipment arranged in a structural stack that allows for increased density of power and cooling generation and usage. The disclosed equipment enclosures feature a novel volumetric approach to building based on a vertically stacked technical infrastructure that employs a scalable, flexible, structural truss system and standardized architecture. The completed enclosures can encompass electrical generation, power distribution, battery energy storage, cooling and supporting infrastructure. As described in greater detail below, the support equipment can include one or more fuel tanks, power distribution centers (PDCs), generators, and chillers. In some embodiments, each structural stack is comprised of modular elements that can be brought on site in a flat pack configuration and assembled very quickly. Each modular element can adhere to one or more building codes or standards.

The disclosed embodiments provide multiple advantageous benefits over conventional data center equipment installations. For example, the disclosed embodiments can deliver increased capacity for a given site (e.g., twice the capacity or more) as compared to existing installations. Also, the modular design of the disclosed embodiments enables off-site integration and standardization of components (including components supported by multiple supply chain partners, clients, and integrators), and significantly faster installation on-site. In addition, the disclosed embodiments provide an installation that is very scalable in delivery and capacity. As data center needs change, the number of equipment enclosures can be increased or decreased to fit the data center requirements. Each equipment enclosure can be installed on-site systematically, regardless of geography.

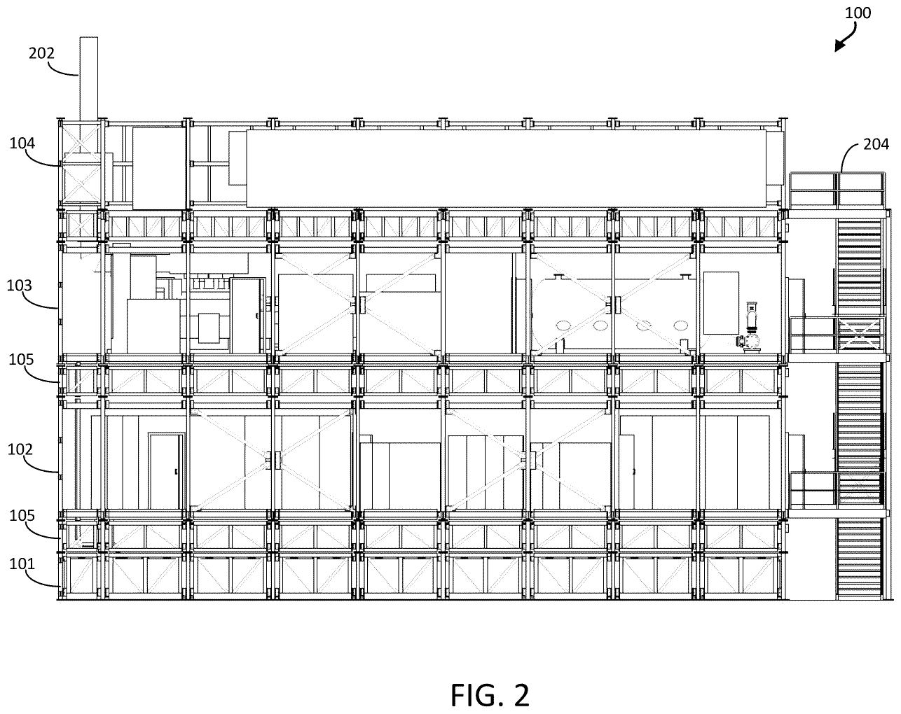

FIGS. 1 and 2 illustrate an example stacked enclosure 100 for data center support equipment according to this disclosure. In particular, FIG. 1 shows an exploded perspective view of the stacked enclosure 100, and FIG. 2 shows an elevation view of the stacked enclosure 100 with exterior cladding removed. The embodiment of the stacked enclosure 100 shown in FIGS. 1 and 2 is for illustration only. Other embodiments of the stacked enclosure 100 could be used without departing from the scope of this disclosure.

As shown in FIGS. 1 and 2, the stacked enclosure 100 includes multiple structural modules, including a fuel storage module 101, a PDC module 102, a generator module 103, and a chiller module 104 arranged in a vertically oriented stack. The stacked enclosure 100 also includes one or more interstitial layers 105 disposed between structural modules. For example, as shown in FIGS. 1 and 2, one interstitial layer 105 is disposed between the fuel storage module 101 and the PDC module 102, and another interstitial layer 105 is disposed between the PDC module 102 and the generator module 103. In combination, the structural modules/layers 101-105 of the stacked enclosure 100 provide all technical infrastructure for a hyperscale data center. The fuel storage module 101, the PDC module 102, the generator module 103, and the chiller module 104 are described in greater below.

Each interstitial layer 105 comprises a three foot high open section through which piping, cabling, conduits, and the like, can extend. The piping, cabling, conduits, and the like, extend between different ones of the structural modules 101-104 and are configured to carry air, fuel, water, electricity, data, or a combination of these. This enables integration of different technologies and components between structural modules 101-104, as described in greater detail below. Each interstitial layer 105 can also include one or more louvers, vents, and the like, in the side walls to allow wind to pass through the stacked enclosure 100. This reduces lateral wind load on the sides of the stacked enclosure 100, which can be over 40 feet tall in some implementations. While the interstitial layers 105 are described as having a height of three feet, other heights are possible, such as heights between one foot and four feet, or higher.

In the example shown in FIGS. 1 and 2, each module 101-105 is approximately 65 feet in length and approximately 15 feet in width. The fuel storage module 101 is approximately 5 feet tall. The PDC module 102 and the generator module 103 are approximately 12 feet tall. The chiller module 104 is an open-air module and its vertical height is not defined by exterior walls, but by the height of the components comprising the chiller module 104. Most of the chiller module 104 is approximately 9 feet tall or less, however an exhaust stack 202 (shown in FIG. 2) disposed on the chiller module 104 is approximately 20 feet tall. The interstitial layers 105 are approximately 3 feet tall. Of course, all of these sizes are merely examples; other sizes are possible and within the scope of this disclosure. In general, the PDC module 102 and the generator module 103 have a vertical height tall enough to allow one or more personnel to comfortably stand and walk around inside the module 102 and 103, such as a height of at least 7 feet.

Each module 101-105 provides resources and functions to the modules 101-105 above and below. In some embodiments, one or more standards documents sets out various detailed requirements. Each module 101-105 may be provided in whole or in part by authorized third parties.

The stack enclosure 100 includes a pinning system that enables easy vertical assembly of the modules 101-105. For example, vertical pins positioned around the perimeter of the top (or bottom) surface of a module 101-105 can be matched to corresponding holes on the bottom (or top) surface of an adjoining module 101-105. That is, the vertical pins can be inserted into the corresponding holes in order to connect the two adjoining modules 101-105. The fuel storage module 101, which is disposed on the bottom of the stacked enclosure 100, can be installed on caissons or a concrete slab. The caissons or concrete slab can also include pins or holes that align with corresponding holes or pins of the fuel storage module 101. Each module 101-105 can be lifted with a crane and lowered into place, allowing for rapid assembly of the stacked enclosure 100. In some embodiments, certified lifting rigs can be part of the design of the stack enclosure 100.

Each module 101-105 includes piping and wiring components (and any other suitable systems) already in place when the modules 101-105 are delivered to the installation location. Wiring and piping that extend between modules 101-105 are already installed to align with each other. For example, a fuel supply pipe that extends between the fuel storage module 101 and the generator module 103 can include pipe components already installed in the fuel storage module 101, the PDC module 102, the interstitial layers 105, and the generator module 103 when the modules 101-105 are delivered on-site. To make the stacked enclosure 100 operable, it is only necessary to complete trivial wiring and piping couplings between adjacent modules 101-105.

One or more modules 101-105 can be configured with a wall knock-down structure, such that the walls are in a folded down configuration at the time of delivery to the installation location. Once on-site, the walls can be raised, and equipment installed inside. This allows for delivery of the entire frame structure of the stack in smaller transport units.

At least some of the modules 101-105 are constructed with a truss frame, which provides structural support for the entire stacked enclosure 100. The truss frames can be formed with adequate strength such that the entire stacked enclosure 100 can accommodate wind and seismic loads as required by code.

As shown in FIG. 2, the stacked enclosure 100 also includes the exhaust stack 202 and one or more external passageways 204, which can include stairways that extend between the modules 101-105 for movement of personnel between the modules 101-105. In some embodiments, the stacked enclosure 100 is designed for all seismic and wind zones in the US, Canada, and/or any other geographic region. In addition, the stacked enclosure 100 can be designed to be compliant with any applicable regulations, including NEC, OSHA, NFPA, and EPA.

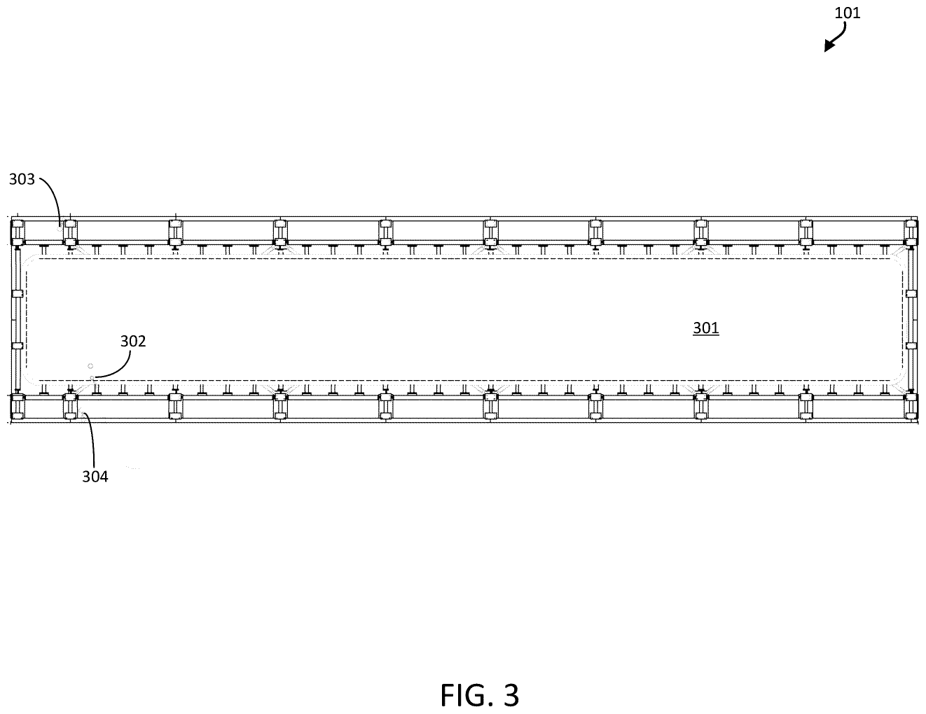

FIG. 3 illustrates further details of the fuel storage module 101 according to this disclosure. In particular, FIG. 3 shows a top view of the fuel storage module 101. The embodiment of the fuel storage module 101 shown in FIG. 3 is for illustration only. Other embodiments of the fuel storage module 101 could be used without departing from the scope of this disclosure.

As shown in FIG. 3, the fuel storage module 101 includes a fuel tank 301 configured to hold fuel (e.g., diesel fuel) used to power at least one generator disposed in the generator module 103. In some embodiments, the fuel tank 301 has a capacity of approximately 11,600 gallons, is approximately 30 inches high, and occupies most (e.g., substantially all) of the horizontal cross section of the fuel storage module 101. Of course, other sizes and capacities of the fuel tank 301 are possible (e.g., 2000 gallon, 5000 gallon, 20,000 gallon, and the like) and within the scope of this disclosure.

In some embodiments, the fuel storage module 101 is constructed with openings on one or both ends to allow access to remove or replace the fuel tank 301 from the end of the fuel storage module 101 without disturbing any of the modules 102-105 above the fuel storage module 101. This contrasts with conventional systems in which the fuel tank provides a supportive structure for other parts, and thus is not easily removable.

The fuel storage module 101 also includes other components, including one or more fuel lines 302 connecting the fuel tank 301 with the generator and any other possible components that operate using fuel. The fuel storage module 101 can also include passage spaces through which incoming power cables 303 and outgoing power cables 304 can extend. The incoming power cables 303 can originate at an on-site underground routing location (or another suitable location) and connect the routing location to the PDC module 102. The outgoing power cables 304 can originate in the PDC module 102 and extend to one or more adjacent stacked enclosures 100.

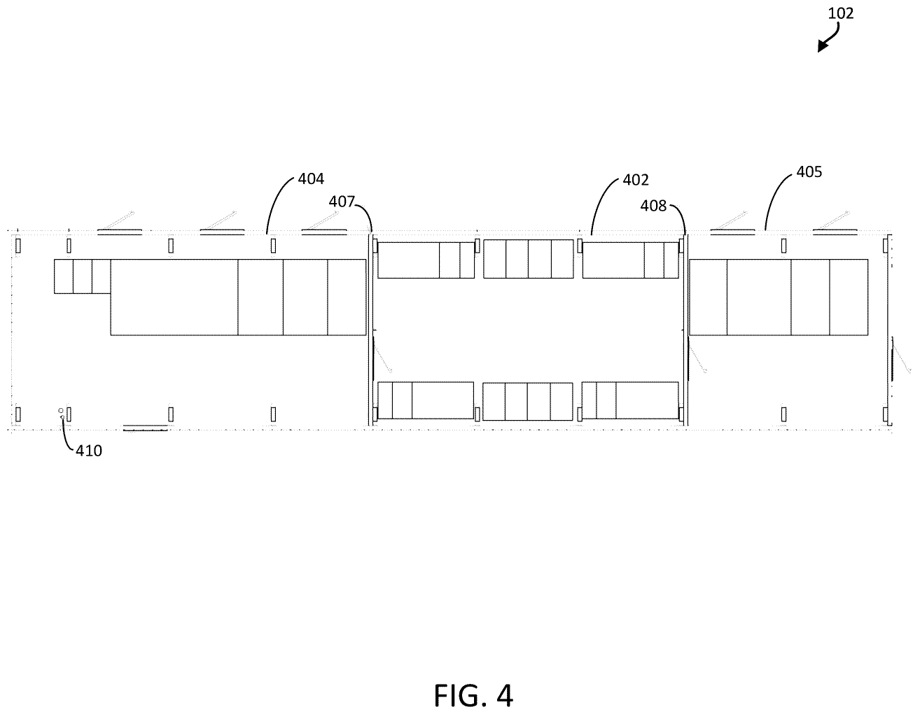

FIG. 4 illustrates further details of the PDC module 102 according to this disclosure. In particular, FIG. 4 shows a top view of the PDC module 102. The embodiment of the PDC module 102 shown in FIG. 4 is for illustration only. Other embodiments of the PDC module 102 could be used without departing from the scope of this disclosure.

The PDC module 102 provides the PDC space for the data center. In typical data center facilities, PDCs are electrical rooms that house uninterruptible power supply (UPS) modules and batteries. Many PDCs can also include specialized additional cooling systems (e.g., DX cooling, also referred to as split system cooling) that maintain the ambient air temperature inside the room between 77° F. to 104 F, depending on the type of batteries and UPS module installed.

As shown in FIG. 4, the PDC module 102 includes a UPS room 402 that houses multiple UPS modules positioned along the walls. The UPS room 402 receives chilled water from the chiller module 104 for cooling. The UPS room 402 can also include one or more ceiling or under-floor mounted evaporators to help cool the interior space of the UPS room 402.

The PDC module 102 also includes equipment rooms 404 and 405 disposed on either side of the UPS room 402. The equipment rooms 404 and 405 house various equipment that supports the UPS modules, such as medium voltage equipment, UPS battery systems, low-voltage equipment, transformers, generators, input breakers, output breakers, reserve bus connections, and the like. Partition walls 407 and 408 separate the equipment rooms 404 and 405 from the UPS room 402. The equipment rooms 404 and 405 can include vents on the exterior walls (which may be controlled by powered louvers) to allow ambient exterior air ventilation for cooling of the UPS equipment.

The PDC module 102 also includes a raceway system that houses busway, cabling, and/or piping embedded in the floor space of the PDC module 102. In some embodiments, the raceway system is concealed under one or more floor portals that can be opened to allow access to the raceway. In some embodiments, the raceway can occupy approximately five inches of vertical space between the bottom of the PDC module 102 and the interior floor on which the equipment is placed. In some embodiments, the PDC module 102 achieves impedance balancing and matching in the raceway by utilizing busway in lieu of cabling. Busway also provides for flexibility in UPS manufacturers for both current and future installations.

The PDC module 102 also includes features for interconnectivity with other modules 101, 103, 104 of the stacked enclosure 100. For example, the PDC module 102 can include one or more fuel lines 410 that extend vertically from the fuel tank 301 below to the generator module 103 above. The fuel lines 410 can be included in the PDC module 102 during the manufacturing of the PDC module 102, and then connected to the fuel tank 301 and the generator module 103 when the stacked enclosure 100 is assembled on-site.

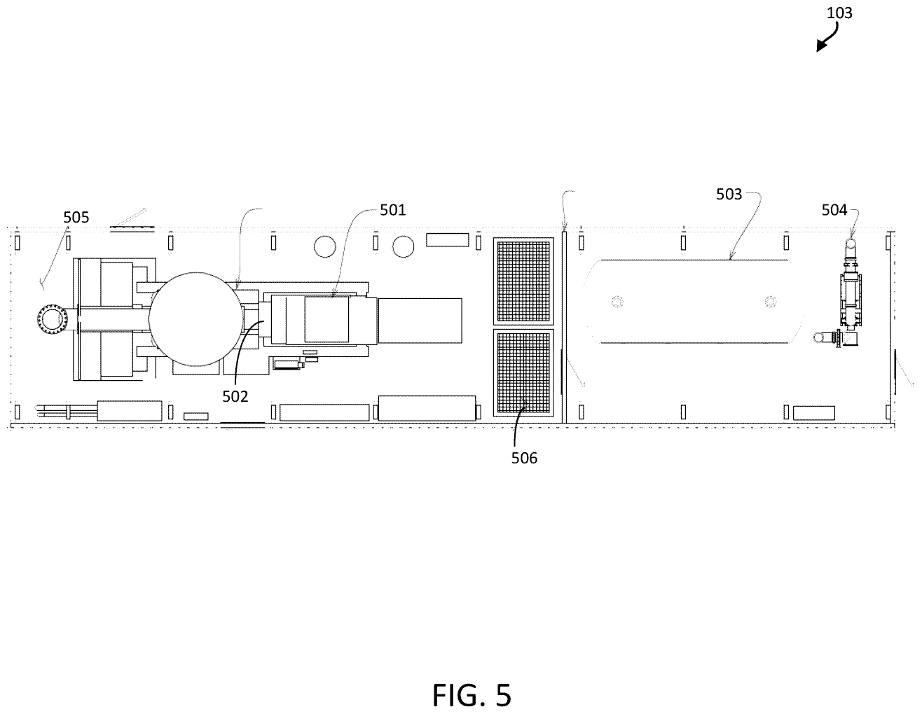

FIG. 5 illustrates further details of the generator module 103 according to this disclosure. In particular, FIG. 5 shows a top view of the generator module 103. The embodiment of the generator module 103 shown in FIG. 5 is for illustration only. Other embodiments of the generator module 103 could be used without departing from the scope of this disclosure.

As shown in FIG. 5, the generator module 103 includes a generator 501, a diesel engine 502 for powering the generator 501, and a water storage tank 503, which stores water (e.g., chilled water) used for the chiller module 104. In some embodiments, the generator 501 is a 3 MW generator sized for 2 MW of data center load. The generator 501 can be used, for example, during a utility shutdown or other outage; in such a case, the generator 501 can provide power to the data center. During operation, the diesel engine 502 receives fuel from the fuel tank 301 and powers the generator 501. The water storage tank 503 is provided to ride through during a transition from utility power to startup of the generator 501. The capacity of the water storage tank 503 can be, e.g., 4000 gallons for 2 MW of data center load. Of course, other sizes of generator 501, diesel engine 502, and water storage tank 503 are possible and within the scope of this disclosure.

The generator module 103 also includes a pump package 504 configured to pump water from the water storage tank 503 up to the chiller module 104. In some embodiments, the pump package 504 can be part of a loop feed for supply and return water that enter into the PDC module 102 and/or other portions of the stacked enclosure 100. The generator module 103 also includes a hot air exhaust plenum 505 that provides an exhaust path for air heated by the generator 501, so as to move the heated air up and away from the rest of the equipment. Ultimately, the heated air is exhausted above the top surface of the stacked enclosure 100, thus reducing noise and thermal impact on neighboring properties.

The generator module 103 also includes multiple air intakes 506 disposed in the floor and/or sides of the generator module 103. In some embodiments, the air intakes 506 are configured as one or more grates in the floor. The air intakes 506 are fluidly coupled to the interstitial layer 105 below the generator module 103, which allows for ambient external air to enter the generator module 103. In operation, the ambient air enters and passes through the interstitial layer 105 (e.g., via one or more louvers, vents, or the like, in the side walls), enters the generator module 103 through the air intakes 506, blows across the generator 501 and the engine 502, and then the heated air is exhausted through the plenum 505 and up to the top of the stack 202 above the height of the chiller module 104. As shown in FIG. 2, the stack 202 extends significantly above the height of the chiller module 104 so that the heated exhaust air does not mix with the intake air around the chiller module 104. Exhaust from the generator 501 can be included in the heated exhaust airstream to facilitate moving the generator exhaust away from the stacked enclosure 100 and surrounding areas.

The generator module 103 also includes a cabling and piping raceway system encompassing approximately five inches of vertical space below the floor of the generator module 103, similar to the raceway system in the PDC module 102, described above. In some embodiments, the floor also can have a spill containment system around at least the engine 502; the spill containment system is provided to contain any fuel or other fluid that may spill or leak out of the engine 502.

In some embodiments, the generator module 103 can be constructed with openings on one or both ends to allow access to remove or replace components (such as the generator 501) from the end of the generator module 103 without disturbing any of the other modules 101, 102, 104, 105.

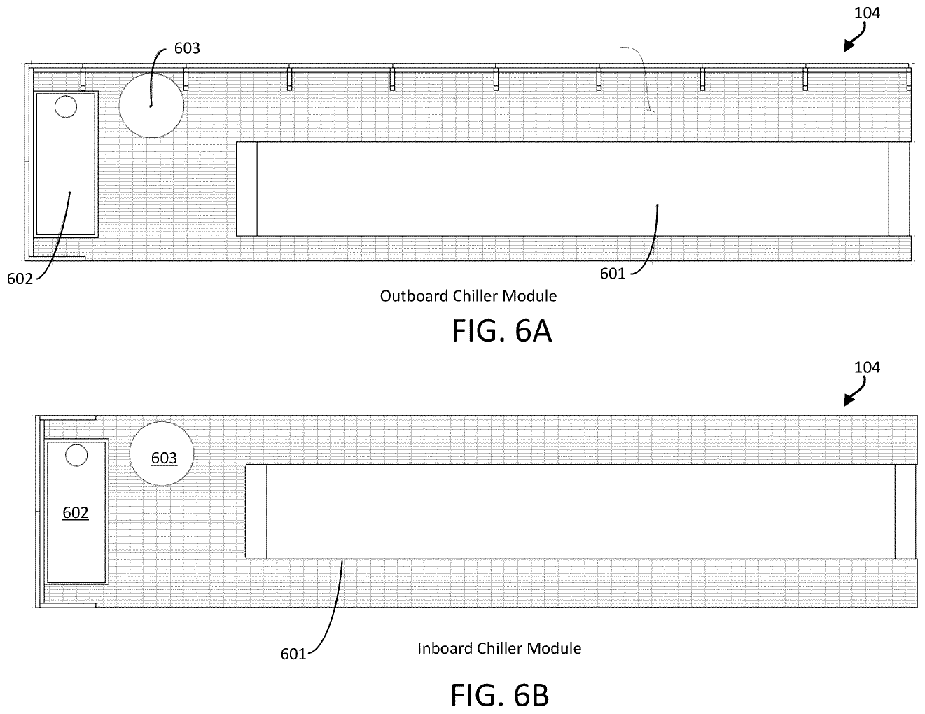

FIGS. 6A and 6B illustrate further details of the chiller module 104 according to this disclosure. In particular, FIG. 6A shows a top view of an outboard configuration of the chiller module 104, and FIG. 6B shows a top view of an inboard or single configuration of the chiller module 104. The embodiments of the chiller module 104 shown in FIGS. 6A and 6B are for illustration only. Other embodiments of the chiller module 104 could be used without departing from the scope of this disclosure.

As shown in FIGS. 6A and 6B, the chiller module 104 includes multiple chiller units 601 disposed on the top surface of the chiller module 104. The chiller units 601 provide cooled water for cooling the data center. For example, in some embodiments, the chiller units 601 in the chiller module 104 can provide approximately 600 tons of cooling for 2 MW of data center load. The chiller units 601 include various piping that connect the chiller units 601 to the water storage tank 503 in the generator module 103. The piping can include multiple pipes—intake and outlet—to form a complete supply and return water loop. In some embodiments, the piping can run through portions of the interstitial layer 105 between the chiller module 104 and the generator module 103 below.

The location of the chiller units 601 on the top surface of the chiller module 104 can depend on whether the stacked enclosure 100 is a single enclosure, an inboard enclosure, or an outboard enclosure. In some data center implementations, only a single stacked enclosure 100 is installed on-site. In other implementations, multiple stacked enclosures 100 are installed side by side. Stacked enclosures on the ends of a multi-stack arrangement are referred to as outboard enclosures, while stacked enclosures in the middle portion (i.e., not on the ends) of the multi-stack arrangement are referred to as inboard enclosures. As shown in FIG. 6A, for an outboard enclosure, the chiller units 601 are positioned closer to one edge of the chiller module 104. As shown in FIG. 6B, for a single enclosure or inboard enclosure, the chiller units 601 are positioned substantially in the center of the chiller module 104.

The chiller module 104 also includes a selective catalytic reduction (SCR) unit 602 and a urea tank 603 provided for scrubbing exhaust from the diesel engine 502. During operation, exhaust enters the bottom of the SCR unit 602, is mixed with urea from the tank 603, which removes sulfur dioxide and any other pollutants from the exhaust, and then is exhausted out the top of the SCR unit 602 through the stack 202.

As discussed above, each module 101-105 is constructed with a truss frame, which provides structural support for the entire stacked enclosure 100. The truss frames can be formed with adequate strength such that the entire stacked enclosure 100 can accommodate wind and seismic loads as required by code. In some embodiments, each module 101-105 employs a scalable, flexible, and standardized truss system architecture.

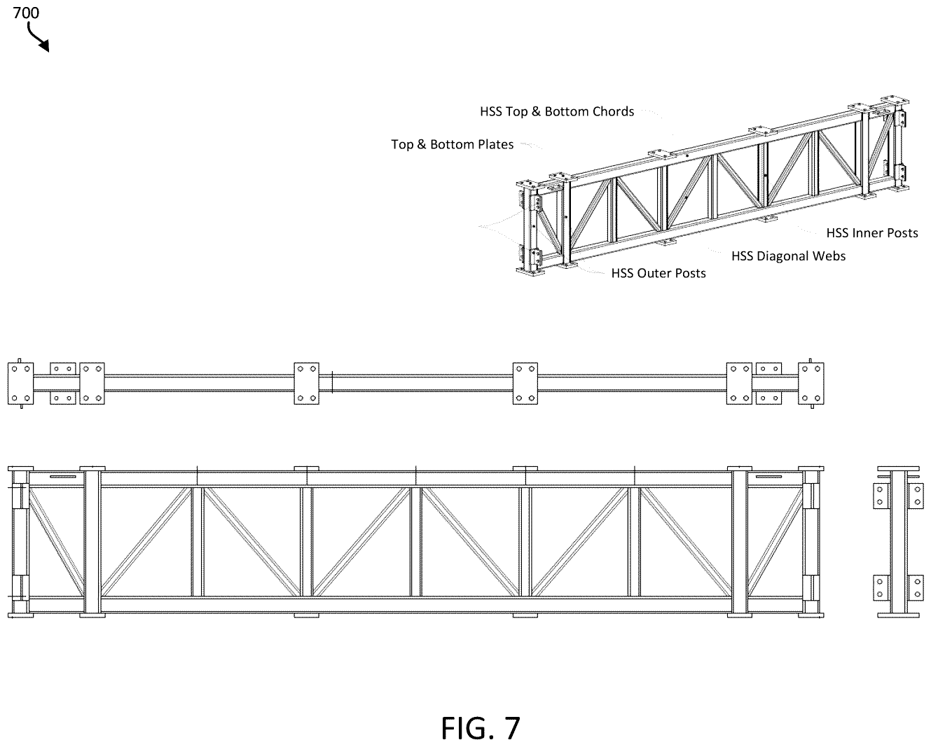

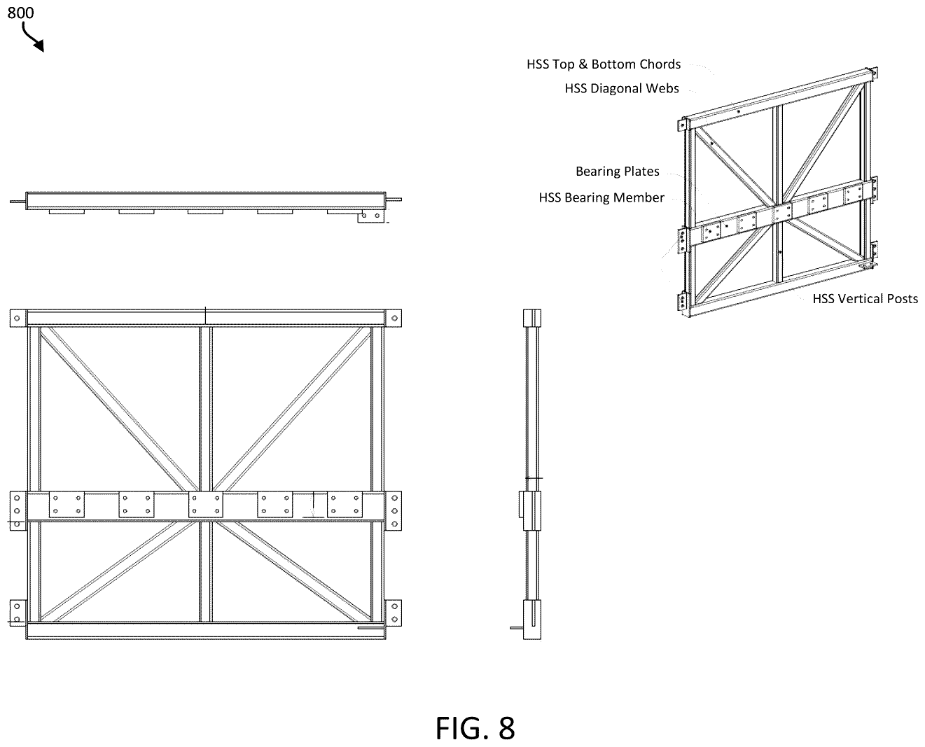

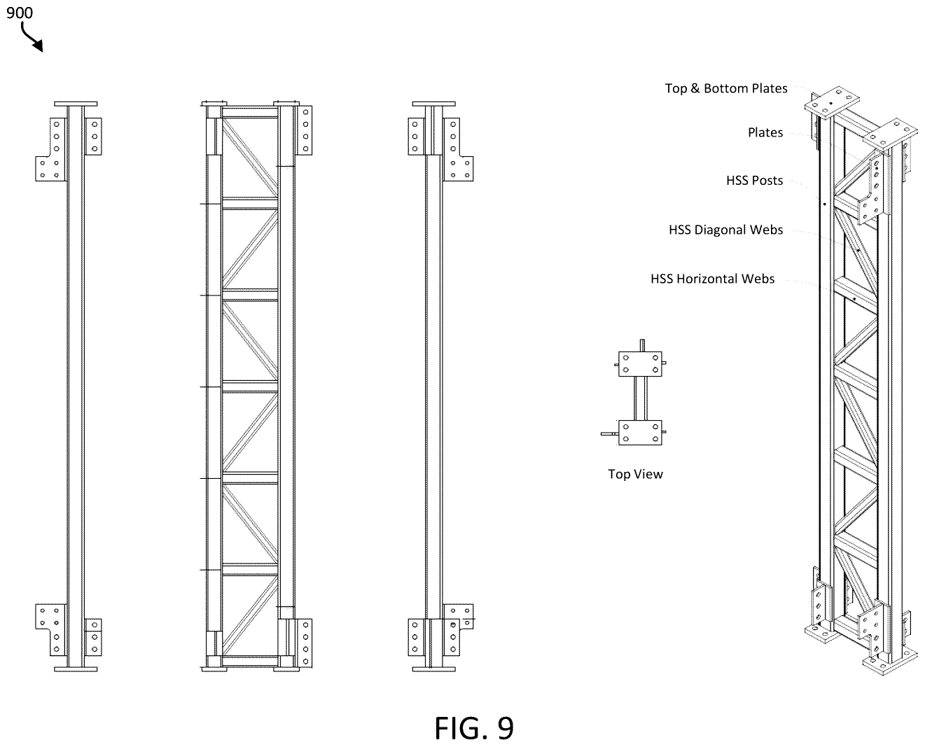

For example, FIGS. 7 through 9 illustrate example trusses 700, 800, 900 that can be used in the construction of one or more modules 101-105 according to this disclosure. In particular, FIG. 7 shows different views of a bracing truss 700, FIG. 8 shows different views of a girder truss 800, and FIG. 9 shows different views of a column truss 900. The various trusses 700, 800, 900, once manufactured, can be flat packed and shipped to the installation location (e.g., the data center site), and then bolt assembled into the modules 101-105.

Each stacked enclosure 100 can include components to support data center loads of various sizes, such as 3 MW, 5 MW, 10 MW, or larger. Each stacked enclosure 100 is self-supporting; that is, in many site installations, there is no need for multiple stacked enclosures 100 adjacent to each other. However, for scalability (such as to achieve hundreds of MW of load capacity), multiple stacked enclosures 100 can be placed together. When multiple stacked enclosures 100 are used, connective wiring and/or piping can be used so that the multiple stacked enclosures 100 can share chilled water, electrical power, air flow, or the like.

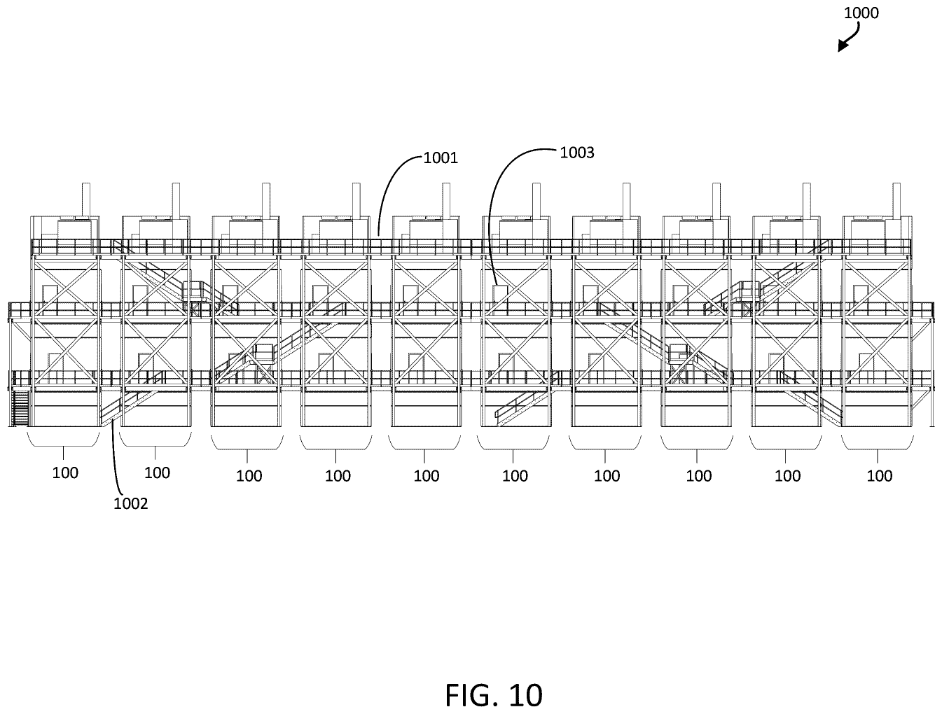

For example, FIG. 10 illustrates an elevation view of an example data center installation 1000 that includes multiple stacked enclosures 100 according to this disclosure. As shown in FIG. 10, ten stacked enclosures 100 are arranged together in a horizontally oriented row. In some embodiments, the stacked enclosures 100 are on approximately 20 foot spacings center to center. For a 15 foot wide stacked enclosure 100, that leaves approximately 5 feet between adjacent stacked enclosures 100 for movement of people and equipment, and air circulation.

As shown in FIG. 10, various pathways, including catwalks 1001 and staircases 1002, can be installed around and between the stacked enclosures 100. A pinning system (such as described earlier) can be used to facilitate installation of the pathways. In addition, one or more doors or portals 1003 can be included in exterior walls of the stacked enclosures 100 for ingress/egress of personnel working in the stacked enclosures 100. While FIG. 10 shows ten stacked enclosures 100, additional stacked enclosures 100 can be easily added to the left or right (or stacked enclosures 100 can be removed) as needed for scalability.

Although FIGS. 1 through 10 illustrates example of a stacked enclosure 100 and related details, various changes may be made to FIGS. 1 through 10. For example, various components in the stacked enclosure 100 may be combined, further subdivided, replicated, rearranged, or omitted and additional components may be added according to particular needs. In addition, while FIGS. 1 through 10 illustrate an example stacked enclosure for equipment for used in data centers, the described functionality may be used in any other suitable device or system.

It may be advantageous to set forth definitions of certain words and phrases used throughout this patent document. The term “couple” and its derivatives refer to any direct or indirect communication between two or more elements, whether or not those elements are in physical contact with one another. The terms “transmit”, “receive”, and “communicate”, as well as derivatives thereof, encompass both direct and indirect communication. The terms “include” and “comprise”, as well as derivatives thereof, mean inclusion without limitation. The term “of” is inclusive, meaning and/or. The phrase “associated with”, as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “such as” when used among terms, means that the latter recited term(s) is(are) example(s) and not limitation(s) of the earlier recited term. The phrase “at least one of” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Definitions for other certain words and phrases are provided throughout this patent document. Those of ordinary skill in the art should understand that in many if not most instances, such definitions apply to prior as well as future uses of such defined words and phrases. Although the present disclosure has been described with an exemplary embodiment, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claim scope. The scope of the patented subject matter is defined by the claims.

What is claimed is:

1. A system comprising:
a stacked enclosure comprising multiple structural modules arranged in a vertically oriented stack, each structural module disposed at a different vertical level, each structural module having a substantially same footprint, each structural module configured to house support equipment for a data center; and
one or more interstitial layers disposed between adjacent structural modules.

2. The system of claim 1, wherein the support equipment comprises one or more fuel tanks, one or more power distribution centers (PDCs), one or more generators, and one or more chillers.

3. The system of claim 1, wherein at least some of the structural modules or interstitial layers comprises vertical pins arranged around a perimeter of a top or bottom surface of that structural module or interstitial layer, wherein the vertical pins are configured to be inserted into corresponding holes on a bottom or top surface of an adjoining structural module or interstitial layer.

4. The system of claim 1, wherein at least some of the structural modules are constructed with a truss frame.

5. The system of claim 1, wherein the stacked enclosure further comprises one or more external passageways having at least one stairway that extends between two or more of the structural modules.

6. The system of claim 1, further comprising:
one or more pipes, cables, or conduits extending between different ones of the structural modules and configured to carry one or more of: air, fuel, water, electricity, or data.

7. The system of claim 1, wherein at least one of the structural modules has a height of at least 7 feet.

8. The system of claim 1, wherein the structural modules comprise a fuel storage module, a PDC module, a generator module, and a chiller module.

9. The system of claim 8, wherein the fuel storage module includes a fuel tank configured to hold fuel used to power at least one generator disposed in the generator module.

10. The system of claim 9, wherein the fuel tank has a capacity of at least 5,000 gallons and occupies substantially all of a horizontal cross section of the fuel storage module.

11. The system of claim 8, wherein the PDC module includes at least one uninterruptible power supply (UPS) module and at least one battery.

12. The system of claim 8, wherein the PDC module comprises a raceway system embedded in a floor space of the PDC module, the raceway system configured to house at least one of: busway, cabling, or piping.

13. The system of claim 8, wherein the generator module comprises at least one generator and at least one engine configured to power the generator.

14. The system of claim 13, wherein the generator module further comprises a water storage tank and a pump package configured to power water from the water storage tank to the chiller module.

15. The system of claim 8, wherein:
a first interstitial layer of the one or more interstitial layers is disposed below the generator module;
the generator module comprises one or more air intakes disposed in a floor of the generator module; and
the one or more air intakes are fluidly coupled to the first interstitial layer, such that ambient air passes through the first interstitial layer and enters the generator module through the one or more air intakes.

16. A system comprising:
multiple stacked enclosures arranged adjacent each other in a row, each stacked enclosure comprising:
multiple structural modules arranged in a vertically oriented stack, each structural module disposed at a different vertical level, each structural module having a substantially same footprint, each structural module configured to house support equipment for a data center; and
one or more interstitial layers disposed between adjacent structural modules.

17. The system of claim 16, wherein the support equipment comprises one or more fuel tanks, one or more power distribution centers (PDCs), one or more generators, and one or more chillers.

18. The system of claim 16, wherein at least some of the structural modules or interstitial layers comprises vertical pins arranged around a perimeter of a top or bottom surface of that structural module or interstitial layer, wherein the vertical pins are configured to be inserted into corresponding holes on a bottom or top surface of an adjoining structural module or interstitial layer.

19. The system of claim 16, wherein at least some of the structural modules are constructed with a truss frame.

20. The system of claim 16, wherein at least one of the multiple stacked enclosures further comprises one or more external passageways having at least one stairway that extends between two or more of the structural modules.
